(19) United States
(12) Patent Application Publication
(10) Pub. No.: US 2007/0296515 A1
(43) Pub. Date: Dec. 27, 2007

(54) MAGNETRON

(75) Inventors: Naoya KATO, Hokkaido (JP); Masatoshi HIGASHI, Hokkaido (JP); Toshio KAWAGUCHI, Kanagawa (JP); Shinji HAYASHI, Hokkaido (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: TOSHIBA HOKUTO ELECTRONICS CORPORATION, Asahikawa-shi (JP)

(21) Appl. No.: 11/765,081

(22) Filed: Jun. 19, 2007

(30) Foreign Application Priority Data
Jun. 19, 2006 (JP) 2006-168505

(51) Int. Cl. H03C 3/32

(52) U.S. Cl. 332/132

(57) ABSTRACT

At an oscillation frequency of 2450 MHz band, number of the vanes constituting the anode part of the magnetron being, the diameter 2ra of the circle inscribing tip portions of the vanes on the cathode side being 8.0 to 8.8 mm, the diameter 2rc of the outer periphery of the filament constituting the cathode part being 3.5 to 3.9 mm, the height A3 of the vane in the direction of the tube axis is 7.0 to 8.0 mm, the mutual distance A1 between the bases of the pair of funnel-shaped pole pieces fixed to both sides of the anode part being 21.5 to 23.5 mm, the mutual distance A2 between the bottom portions of the pair of pole pieces being 10.2 to 11.2 mm, the inner diameter P1 of the through-hole of the pole piece being 8.3 to 8.5 mm, and the outer diameter P2 of the bottom portion being 11.0 to 16.0 mm are set up.

### CROSS-REFERENCE TO RELATED APPLICATIONS

This application is based upon and claims the benefit of priority Japanese Patent Application No. 2006-168505, filed on Jun. 19, 2006, the entire contents of which are incorporated herein by reference.

### BACKGROUND OF THE INVENTION

1. Field of the Invention

The present invention relates to a magnetron used for a microwave heating apparatus.

2. Description of the Related Art

The magnetron is an electron tube generating microwaves, which is used in a microwave heating apparatus such as a microwave oven. The oscillating body portion of the magnetron is provided with an anode part comprising an anode cylinder and a plurality of vanes radially arranged toward the tube axis from the inner wall of the anode cylinder, and a cathode part having a coil filament arranged along the tube axis of the anode cylinder. The both ends, that is an output part side and an input part side, of the anode cylinder are provided with a pair of funnel-shaped pole pieces with a plane bottom portion where a through-hole is formed at the center thereof face-to-face together. Annular permanent magnets are prepared on the pair of pole pieces respectively (e.g. Refer to Japanese Laid-open Patent No. 2003-132809).

In the configuration mentioned above, the structure is to supply the cathode part with electric power through the input part and to pull out a microwave generated in the oscillating body portion through the output part upon transmitting via an antenna lead.

As to main dimensions of the oscillation body portion of a conventional magnetron, the number of vanes being 10, the diameter 2ra of the circle inscribing the tips of vanes on the cathode side (vane tips) being 8.8 to 9.1 mm, the diameter 2rc of the periphery of the filament being 3.7 to 3.9 mm, the height A3 of the vanes in the direction of the tube axis being 8.5 to 9.5 mm, and the open area ratio of the vane tips μ=Vg/(Vg+Vt) being 0.27 to 0.32 where the distance between adjacent vane tips is designated by Vg and the thickness of the vane is designated by Vt are configured at the oscillation frequency of 2450 MHz band.

In addition to the above, the mutual distance A1 between base portions of a pair of pole pieces fixed to both sides of the anode cylinder being 22.5 to 23.5 mm, the mutual distance A2 between bottom portions of the pair of pole pieces being 11.7 to 12.7 mm, the inner diameter P1 of the through-hole of the pole piece being 9.4 to 9.8 mm, and the outer diameter P2 of the bottom portion of the pole piece being 11.0 to 18.0 mm are also configured. Magnetic flux density Bg obtained in the interaction space is 0.17 to 0.21 tesla when the magnetic force that the existing permanent magnet possesses is converged by the pole piece mentioned above. The permanent magnet is, for example, an annular ferrite magnet having an outer diameter of 50 to 57 mm, an inner diameter of 12 to 22 mm and a thickness of 10 to 13.5 mm.

Oscillation output efficiency of the magnetron is calculated by the ratio of the microwave power emitted from the output part to the input power (anode voltage Va×anode current Ib) applied between the anode part and the cathode part. In a conventional magnetron mentioned above, the oscillation output efficiency becomes 70 to 75% when the anode voltage Va is 3.7 to 4.6 kV and the anode current Ib is 200 to 330 mA. For example, microwave power of 1 kW or more can be outputted if the anode voltage Va of 4.5 kV, the anode current of 300 mA and the oscillation output efficiency of 75% are set.

For development of the magnetron these days, further improvement of the oscillation output efficiency is required in order to save energy. Conventional magnetrons can improve the oscillation output efficiency by 1 to 2% upon raising further the anode voltage Va. To this end, magnetic flux density Bg in the interaction space is needed to be further increased. However, there is a problem that leads to raising the cost of magnetron because the permanent magnet requires to be enlarged or highly performed and the withstand voltage of the driving circuit is necessary to be high to cope with a high voltage.

When a magnetron is newly developed, a designing method to minimize the diameter 2ra of the inscribing circle of the vane tips is employed so that the anode voltage Va will not rise high. However, rise of the cost due to enlarging cannot be evaded because it is necessary for the magnetic flux density Bg in the interaction space to be more enlarged to improve the oscillation output efficiency.

The present invention is intended for a magnetron to improve the oscillation output efficiency thereof and prevent its whole body including the permanent magnets from being enlarged, or make the above whole body be smaller than a conventional one.

### BRIEF SUMMARY OF THE INVENTION

A magnetron according to the present invention is characterized in that it comprises;

an anode part comprising an anode cylinder and a plurality of vanes arranged radially from an inner wall of the anode cylinder toward a tube axis,

a cathode part having a coil filament arranged along the tube axis of the anode cylinder,

a pair of funnel-shaped pole pieces arranged at both ends, that is an output part side and an input part side, respectively of the anode cylinder face-to-face together and having a base portion secured to the anode cylinder and a bottom portion provided with a through-hole at a central portion thereof, and

a pair of annular permanent magnets arranged outside the pair of the pole pieces respectively;

and being configured by, at an oscillation frequency of 2450 MHz band, number of the vanes being 10, a diameter of a circle inscribing tip portions of the vanes on the cathode side being 8.0 to 8.8 mm, a diameter of an outer periphery of the filament being 3.5 to 3.9 mm, a height of the vane in a direction of the tube axis being 7.0 to 8.0 mm, a mutual distance between the base portions of the pair of pole pieces being 21.5 to 23.5 mm, a mutual distance between the bottom portions of the pair of pole pieces being 10.2 to 11.2 mm, an inner diameter of the through-hole of the pole piece being less than 8.5 mm, preferably 8.3 to 8.5 mm and an outer diameter of the bottom portion being 11.0 to 16.0 mm. Furthermore, the inner diameter of the through-hole of the pole piece on the output part side can be smaller than the inner diameter of the through-hole of the pole piece on the input part side.

In accordance with the present invention, improvement of the oscillation output efficiency without enlarging the whole body including the permanent magnets with respect to a magnetron can be put into practice.

### BRIEF DESCRIPTION OF THE DRAWINGS

FIG. 1 is a cross-sectional view of the main part of the magnetron relating to an embodiment of the present invention.

FIG. 2A is a schematic top views where the essential portion of the anode part and the cathode part of the magnetron relating to an embodiment of the present invention is extracted, and FIG. 2B is an enlarged cross-sectional view of the pole pieces.

FIG. 3 is a correlation diagram between the interaction space magnetic flux density Bg (compared to a conventional one) and the electron efficiency ηe (compared to a conventional one).

FIG. 4 is a correlation diagram between the interaction space magnetic flux density Bg (compared to a conventional one) and the diameter 2ra (compared to a conventional one) of the inscribing circle of the vane tips when the anode voltage Va is constant.

FIGS. 5A and 5B are diagrams explaining the effect of the magnetic circuit of a magnetron by means of correlation between the outer diameter P2 of the bottom portion of the pole piece and the interaction space magnetic flux density Bg.

FIGS. 6A and 6B are diagrams comparing a magnetron of the present invention with a conventional magnetron by means of correlation between the anode voltage Va and the oscillation output efficiency n.

FIG. 7 is a diagram comparing a magnetron relating to an embodiment of the present invention with a conventional magnetron with respect to main dimensions of the oscillation body portion.

### DETAILED DESCRIPTION OF THE INVENTION

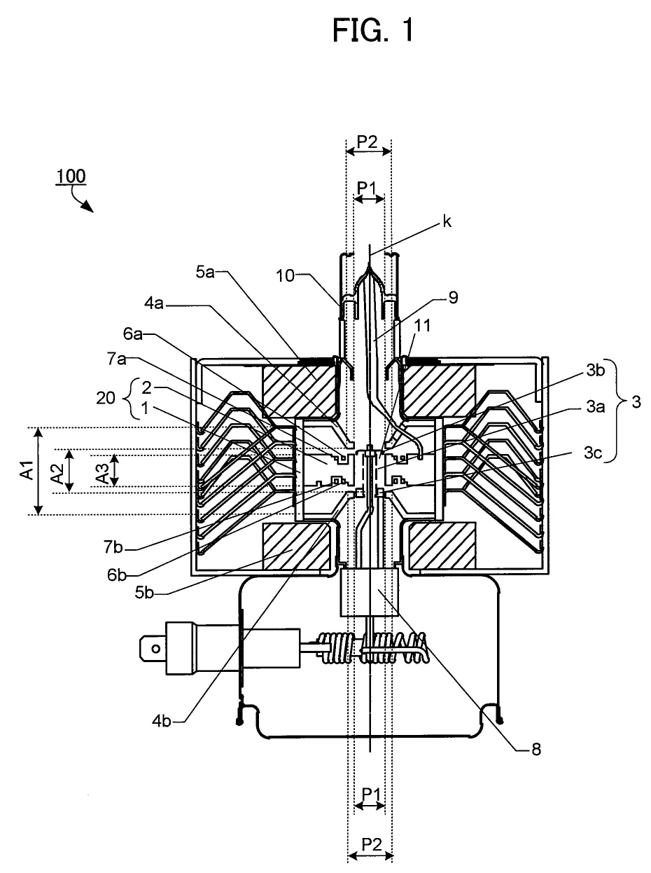

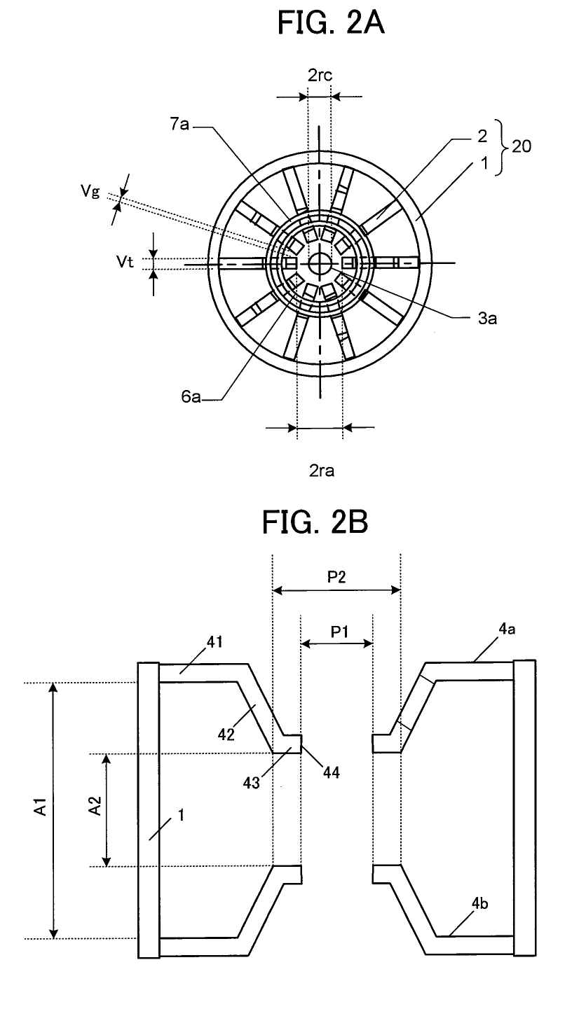

Referring to the drawings, an embodiment of the present invention will be explained hereinafter. FIG. 1 shows the cross sectional view of the substantial part of the main body of magnetron 100 in accordance with this embodiment. FIG. 2A shows a schematic top view in which the essential portion of the anode part 20 and the cathode part 3 of the magnetron 100 is extracted, and FIG. 2B shows a magnified view of the pole pieces 4a and 4b.

As shown in FIGS. 1, 2A and 2B, the oscillation body portion of the magnetron 100 is provided with an anode part 20 formed by an anode cylinder 1 and a plurality of vanes 2 arranged radially at an equal interval toward the tube axis k from the inner wall of the anode cylinder 1, and a cathode part 3 having a coil filament 3a arranged along the tube axis k inside the anode cylinder 1. Both ends of the filament 3a are provided with a pair of end hats 3b and 3c.

The outer end of the vane 2 is secured to the inner wall of the anode cylinder 1 and the inner end thereof is free. A pair of first strap rings 6a, 6b having a smaller diameter and a pair of second strap rings 7a, 7b located outside the first strap rings and having a diameter larger than that of the first strap ring are connected alternately to the upper side (output part side) and the lower side (input part side) of each vane 2. As to the upper sides of vanes 2, for instance, vanes 2 which are odd order ones counted from the first vane 2 are connected together with the first strap ring 6a, and vanes 2 which are even order ones are connected together with the second strap ring 7a. As to the lower sides of vanes 2, to the contrary, vanes which are odd order ones are connected together with the second strap ring 7b and vanes which are even order ones are connected together with the first strap ring 6b.

As shown in FIG. 2B, a pair of funnel-shaped pole pieces 4a, 4b having a base portion 41 secured at both ends, that is an output part side and an input part side respectively of the anode cylinder 1, a tapered portion 42 and a flat bottom portion 43 with a through-hole 44 at the central portion thereof are provided face-to-face together. Annular permanent magnets 5a, 5b are positioned above the pole piece 4a and below the pole piece 4b respectively. The pole pieces 4a, 4b and the permanent magnets 5a, 5b constitute a magnetic circuit of the magnetron 100.

An input part 8 which supplies filament-applying power and a magnetron operating voltage is provided below the pole piece 4b in the direction of tube axis, and an output part 10 which emits a microwave transmitted through an antenna lead 9 is provided over the pole piece 4a in the direction of tube axis.

With the aid of the electric field in the interaction space of the cavity resonator of 2450 MHz band constituted by the vane 2, the first strap rings 6a, 6b and the second strap rings 7a, 7b, the magnetic field in the direction of the tube axis formed by the pole pieces 4a, 4b and the permanent magnets 5a, 5b, the filament-applying power and the magnetron operating voltage supplied from the input part 8, the magnetron has a structure in which thermal electrons emitted from the filament 3a perform orbital motion in the interaction space so as to oscillate a microwave that is transmitted through the antenna lead 9 and emitted from the output part 10.

The oscillation output efficiency n of the magnetron is determined by a product (η=ηe×ηc) of the electron efficiency ηe and the circuit efficiency ηc. The electron efficiency ηe is the motion efficiency of electron, and the circuit efficiency ηc relates to a circuit coefficient such as Joule loss or dielectric loss. The electron efficiency ηe is known that it is represented by the equation (1).

$$η e = 1 - \frac{1 + σ}{( 2 Bg / {B}_{o} ) - 1 + σ} \\ where \\ {B}_{o} = \frac{4 π c {m}_{e}}{{q}_{e} λ ( 1 - σ ) \cdot ( N / 2 )} , \\ σ = \frac{rc}{ra} . \qquad ( 1 )$$

c: velocity of light N: number of vanes

ra: radius of inscribing circle to vane tips

λ: wavelength of oscillation frequency

rc: radius of outer periphery of filament

mₑ: mass of electron

Bg: magnetic flux density of interaction space

qₑ: electric charge of electron.

The anode voltage Va is represented by the equation (2):

$$Va = \frac{2 π c \cdot {ra}^{2} ( 1 - {σ}^{2} )}{N λ} ( Bg - \frac{4 π {cm}_{e}}{{Nq}_{e} λ} ) \qquad ( 2 )$$

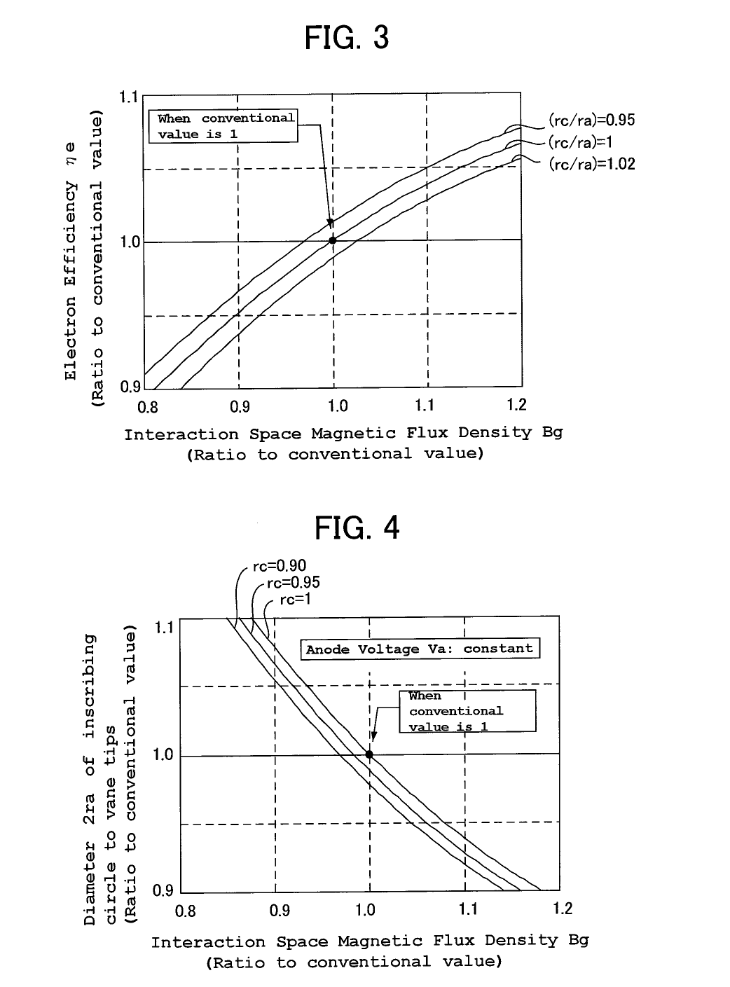

Based on the equation (1) and the equation (2), FIG. 3 shows the relationship between the interaction space magnetic flux density (the magnetic flux density in the interaction space 11) Bg (ratio to the conventional value) and the electron efficiency ηe (ratio to the conventional value), and FIG. 4 shows the relationship between the interaction space magnetic flux density Bg (ratio to the conventional value) when the anode voltage Va is constant and the diameter 2ra of the inscribing circle to the tips of the vane 2 (vane tips) (ratio to the conventional value) on the cathode 3 side. According to FIG. 3, the electron efficiency ηe increases as the interaction space magnetic flux density Bg increases. In addition, the anode voltage Va rises high as the interaction space magnetic flux density increases according to the equation (2).

It is necessary to minimize the diameter 2ra of the inscribing circle of the vane tips (inscribing radius is ra) so that the anode voltage Va will not rise high even if the interaction space magnetic flux density Bg increases according to the equation (2) and FIG. 4. In addition to the above, designing a magnetic circuit for increasing the interaction space magnetic flux density Bg is indispensable in order to improve the oscillation output efficiency 7.

In consequence, for the magnetron 100 of this embodiment, the shape of the pole pieces 4a, 4b was thought out so as to converge the magnetic flux effectively in the interaction space, and moreover, dimensions of the anode part 20 were optimized.

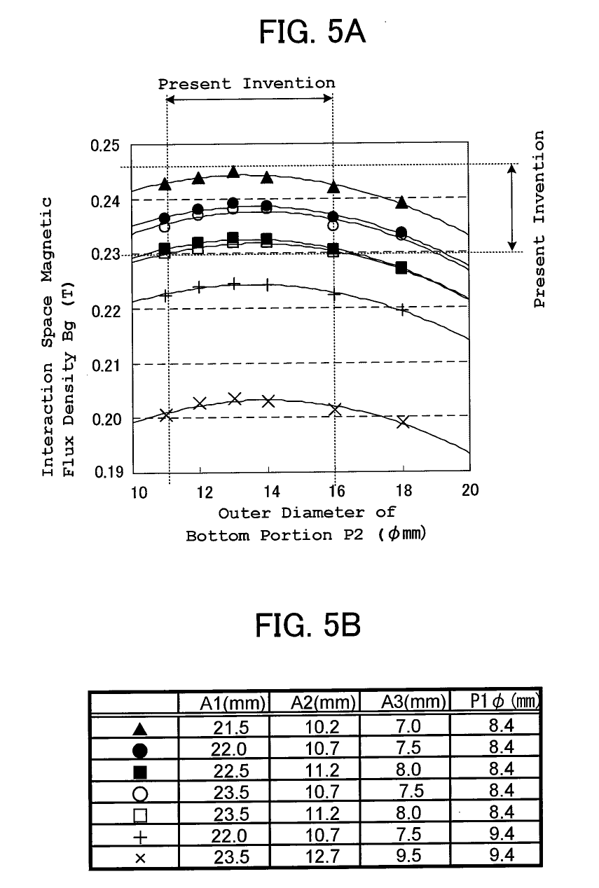

FIGS. 5A and 5B show the measurement result of the interaction space magnetic flux density (the magnetic flux density in the interaction space 11) Bg in the case where the same permanent magnet is used. FIG. 5A shows the measurement result of the value of the interaction space magnetic flux density Bg when the value of the outer diameter P2 of the bottom portions 43 of the pole pieces 4a, 4b is changed to be 11 mm, 12 mm, 13 mm, 14 mm, 15 mm, and 16 mm, for each of the 5 sets. The set above is a combination of the mutual distance A1 between the base portions 41 of the pole pieces 4a, 4b secured to both ends of the anode cylinder 11, the mutual distance A2 between the bottom portions 43 of the pole pieces 4a, 4b, the height A3 of the vane 2 in the direction of the tube axis, and the value of the inner diameter P1 of the through-hole 44 of the pole pieces 4a, 4b as shown in FIG. 5B.

According to the measurement result shown in FIGS. 5A and 5B, whereas the interaction space magnetic flux density Bg is 0.190 to 0.205 in the case of A1, A2, A3, and P1 as denoted by the mark X, the interaction space magnetic flux density Bg can be raised up to 0.230 to 0.245 tesla if A1 being 21.5 to 23.5 mm, A2 being 10.2 to 11.2 mm, A3 being 7.0 to 8.0 mm, P1 being in the vicinity of 8.4 mm (the range of 8.4±0.1 mm), and P2 being 11.0 to 16.0 mm are set up.

As shown in FIG. 4, the diameter 2ra of the inscribing circle of the vane tips was set to be from 8.0 to 8.8 mm so that the anode voltage Va would not be raised even though the interaction space magnetic flux density Bg became large in this embodiment. The open area ratio μ=Vg/(Vg+Vt) of the vane tips was set to be from 0.25 to 0.30 where Vg was the distance between vane tips adjacent to each other and Vt was the thickness of the vane 2.

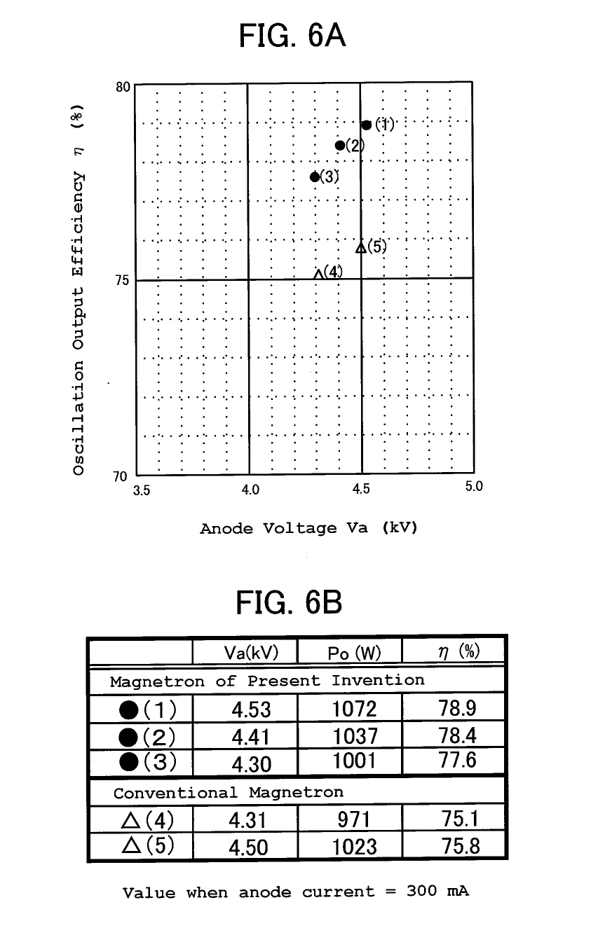

FIGS. 6A and 6B show the result of comparison of the oscillation output efficiency η between the magnetron 100 (the magnetron according to the present invention) of the above-mentioned structure (dimensions) and a conventional magnetron. FIG. 6B shows the result of the oscillation output efficiency η (%) calculated from the anode voltage Va (kV) and the microwave output Po (W) when the anode current Ib is 300 mA. FIG. 6A shows the relationship between the anode voltage Va and the oscillation output efficiency η based on FIG. 6B. It is recognized from FIGS. 6A and 6B that the magnetron according to the present invention has the oscillation output efficiency η improved by 3 to 4% compared to a conventional magnetron. In the configuration mentioned above, the inner diameter of the through-hole of the pole pieces 4a, 4b is set to be P1. Namely, the inner diameter of the through-hole of the pole piece on the output part 10 side and the inner diameter of the through-hole of the pole piece on the input part 8 side are set to have the same value. As a modification thereof, the inner diameter of the through-hole of the pole piece on the output part 10 side can be set to be smaller than the inner diameter of the through-hole of the pole piece on the input part 8 side. In this case, the magnetic flux density in the interaction space 11 can be more raised by setting the diameter at the range of 7.5 to 8.5 mm, for example 7.5 to 8.3 mm. If the inner diameter of the through-hole of the pole piece 4a is set to be 8.0 mm, the magnetic flux density Bg can be raised by about 0.03 to 0.05 tesla.

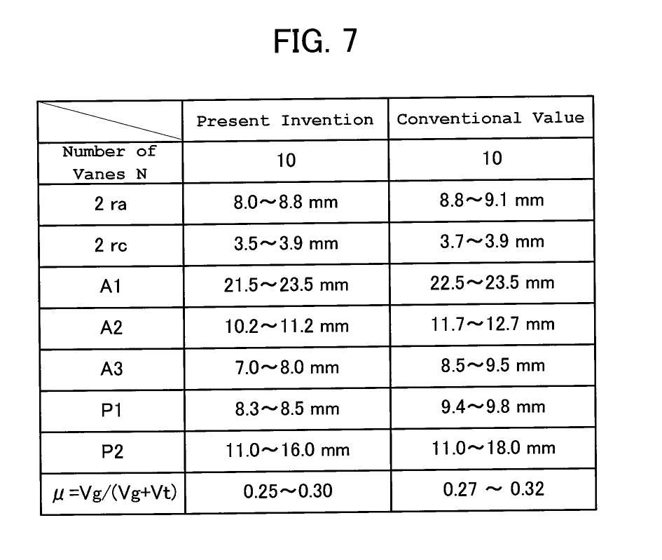

FIG. 7 shows main dimensions of the oscillation body portion about the magnetron 100 relating to an embodiment of the present invention and a conventional magnetron.

As mentioned above, the magnetic flux density Bg obtained in the interaction space 11 can be raised up to 0.210 to 0.245 tesla even with magnetic power of the present permanent magnets 5a, 5b by means of designing dimensions of the magnetic circuit and the anode part smaller in total than conventional one. Moreover, as usual, the oscillation output efficiency η can be improved by 3 to 4% even if the anode voltage Va is from 3.7 to 4.6 kV and the anode current Ib is from 200 to 300 mA.

That is to say, according to the magnetron 100 of this embodiment, the magnetic flux density obtained in the interaction space 11 is increased even with present permanent magnets 5a, 5b, and the oscillation output efficiency can be improved even with a conventional anode voltage. In consequence, improving the oscillation output efficiency without enlarging the whole body including the permanent magnets in respect to a magnetron can be achieved.

What is claimed is:

1. A magnetron comprising;
an anode part comprising an anode cylinder and a plurality of vanes arranged radially from an inner wall of the anode cylinder toward a tube axis,
a cathode part having a coil filament arranged along the tube axis of the anode cylinder,
a pair of funnel-shaped pole pieces arranged at an output part side and an input part side respectively of the anode cylinder face-to-face together and having a base portion secured to the anode cylinder and a bottom portion provided with a through-hole at a central portion thereof, and
a pair of annular permanent magnets each arranged outside the pair of the pole pieces respectively;
and the magnetron being configured by, at an oscillation frequency of 2450 MHz band, number of the vanes being 10, a diameter of a circle inscribing tip portions of the vanes on the cathode side being 8.0 to 8.8 mm, a diameter of an outer periphery of the filament being 3.5 to 3.9 mm, a height of the vane in a direction of the tube axis being 7.0 to 8.0 mm, a mutual distance between the base portions of the pair of pole pieces being 21.5 to 23.5 mm, a mutual distance between the bottom portions of the pair of pole pieces being 10.2 to 11.2 mm, an inner diameter of the through-hole of the pole piece being less than 8.5 mm and an outer diameter of the bottom portion being 11.0 to 16.0 mm.

2. The magnetron as set forth in claim 1 wherein an open area ratio Vg/(Vg+Vt) at the tip of the vane is set to be 0.25 to 0.30 where a distance between adjacent tip portions of the vanes on the cathode side is designated by Vg and thickness of the vane is designated by Vt.

3. The magnetron as set forth in claim 1 wherein the inner diameter of the through-hole of the pole piece is 8.3 mm to 8.5 mm.

4. The magnetron as set forth in claim 1 wherein the inner diameter of the through-hole of the pole piece on the output part side is smaller than the inner diameter of the through-hole of the pole piece on the input part side.

5. The magnetron as set forth in claim 4 wherein the inner diameter of the through-hole of the pole piece on the output part side is 7.5 to 8.3 mm.
